(19) United States
(12) Patent Application Publication
(10) Pub. No.: US 2026/0033002 A1
(43) Pub. Date: Jan. 29, 2026

(54) ARRAY SUBSTRATE AND DISPLAY APPARATUS

(71) Applicants: BOE Technology Group Co., Ltd., Beijing (CN); Beijing BOE Technology Development Co., Ltd., Beijing (CN)

(72) Inventors: Lizhong WANG, Beijing (CN); Yan QU, Beijing (CN); Binbin TONG, Beijing (CN); Hui GUO, Beijing (CN); Ce NING, Beijing (CN); Tianmin ZHOU, Beijing (CN)

(21) Appl. No.: 18/993,562

(22) PCT Filed: Apr. 26, 2023
(86) PCT No.: PCT/CN2023/090872

§ 371 Date: Jan. 12, 2025

(51) Int. Cl. H10D 86/40; H10D 86/60

(52) U.S. Cl. CPC H10D 86/441; H10D 86/60

(57) ABSTRACT

An array substrate and a display apparatus are provided and belong to the field of display technology. The array substrate includes: a substrate, a first signal line and a second signal line on one side of the substrate, the first signal line and the second signal line intersect with each other to define a pixel region, and the array substrate further includes: a first thin film transistor above the substrate and in the pixel region; the first thin film transistor includes: a first semiconductor layer, and the first semiconductor layer includes: a first connection portion, a second connection portion and a third connection portion sequentially connected together; an orthographic projection of the first connection portion on the substrate overlaps with an orthographic projection of the second signal line on the substrate.

### TECHNICAL FIELD

The present disclosure relates to the field of display technology, and in particular to an array substrate and a display apparatus.

### BACKGROUND

With the continuous development of the display technology, products with a high PPI (pixel per inch), such as the augmented reality (AR) display and the virtual reality (VR) display, are getting much attention in the display industry. However, in the products with a high PPI, due to the increase in metal wiring density, etc., AR and VR display products have a greatly reduced aperture ratio and transmittance compared to conventional products.

In order to increase the aperture ratio and transmittance of the AR and VR products, it is necessary to manufacture the AR and VR products by a more complicated process, such as the Low Temperature Poly-silicon and Oxide (LTPO) technology. The LTPO technology integrates low temperature poly-silicon (LTPS) thin film transistors (TFT) and oxide thin film transistors, but has more processes in the manufacturing process, which further increases the production cost. Moreover, the aperture ratio and transmittance of the AR and VR products in the related art still cannot meet the requirements of users for a high aperture ratio and a high transmittance, and therefore, are needed to be further improved.

### SUMMARY

The present disclosure is directed to at least one of the problems in the prior art, and provides an array substrate and a display apparatus.

In a first aspect, embodiments of the present disclosure provide an array substrate including a display region, wherein the array substrate includes: a substrate, a first signal line and a second signal line on one side of the substrate, the first signal line and the second signal line intersect with each other to define a pixel region, and the array substrate further includes: a first thin film transistor above the substrate and in the pixel region; the first thin film transistor includes: a first semiconductor layer, and the first semiconductor layer includes: a first connection portion, a second connection portion and a third connection portion sequentially connected together; extending directions of the first connection portion and the third connection portion are the same as that of the second signal line, an orthographic projection of the first connection portion on the substrate overlaps with an orthographic projection of the second signal line on the substrate, an orthographic projection of the third connection portion on the substrate falls between orthographic projections of two adjacent second signal lines on the substrate, and overlaps with an orthographic projection of the first signal line on the substrate; and a first angle is between extending directions of the second connection portion and the first connection portion, and the first angle is in a range from 90 degrees to 180 degrees.

In some embodiments, the first thin film transistor further includes: a light shielding layer, a second gate insulating layer, a first gate electrode, a second interlayer insulating layer and a first source electrode; and the light shielding layer is above the substrate, the second gate insulating layer covers the first semiconductor layer, the first gate electrode is a part of the first signal line and is on a side of the second gate insulating layer away from the substrate, the second interlayer insulating layer covers the first gate electrode, the first source electrode is a part of the second signal line and is on a side of the second interlayer insulating layer away from the substrate, and the first source electrode is connected to the first connection portion through a corresponding first via extending through the second gate insulating layer and the second interlayer insulating layer.

In some embodiments, a width of the first connection portion is greater than a width of the corresponding first via by 0 to 3 micrometers on at least one side along an extending direction of the first signal line.

In some embodiments, an orthographic projection of the first via on the substrate is outside an orthographic projection of the light shielding layer on the substrate.

In some embodiments, a distance between an edge of the orthographic projection of the first via on the substrate close to the light shielding layer and an edge of the orthographic projection of the light shielding layer on the substrate close to the first via is in a range from 0.5 micrometers to 10 micrometers.

In some embodiments, the array substrate further includes: a first passivation layer on a side of the first source electrode away from the substrate, and a first adapter electrode on a side of the first passivation layer away from the substrate; and the first adapter electrode is connected to the third connection portion through a second via extending through the first passivation layer, the second interlayer insulating layer, and the second gate insulating layer.

In some embodiments, the array substrate further includes: a planarization layer on the first adapter electrode, and a pixel electrode on the planarization layer; and the pixel electrode is connected to the first adapter electrode through a third via extending through the planarization layer.

In some embodiments, the first via has a width in a range from 1.9 micrometers to 2.5 micrometers along an extending direction of the second signal line, the second via has a width in a range from 1.9 micrometers to 2.5 micrometers along an extending direction of the first signal line, and the third via has a width in a range from 2.5 micrometers to 3.0 micrometers along the extending direction of the first signal line.

In some embodiments, an orthographic projection of the third via on the substrate is within an orthographic projection of the light shielding layer on the substrate.

In some embodiments, along an extending direction of the first signal line, a distance between an edge of the orthographic projection of the third via on the substrate and an edge of the orthographic projection of the light shielding layer on the substrate is in a range from 1.0 micrometer to 1.5 micrometers.

In some embodiments, the array substrate further includes: a support structure on the pixel electrode and at a position of the third via; and an extending direction of the support structure is the same as that of the first signal line.

In some embodiments, an orthographic projection of the support structure on the substrate covers an orthographic projection of the third via on the substrate.

In some embodiments, the support structure includes a concave portion at a portion of the support structure corresponding to a spacer supported by the support structure, and an orthographic projection of the concave portion on the substrate overlaps with an orthographic projection of the corresponding third via on the substrate

In some embodiments, the support structure has a slope angle in a range from 30 degrees to 70 degrees.

In some embodiments, the array substrate further includes: a second passivation layer and a common electrode between the pixel electrode and the support structure; and the common electrode is made of a transparent metal.

In some embodiments, the array substrate further includes: a metal layer on the second passivation layer; and an orthographic projection of the metal layer on the substrate is between orthographic projections of adjacent pixel electrodes on the substrate.

In some embodiments, the array substrate further includes a peripheral region on at least one side of the display region, and further includes: a second thin film transistor above the substrate and in the peripheral region; the second thin film transistor includes: a second semiconductor layer, a first gate insulating layer, a second gate electrode, a first interlayer insulating layer, a second source electrode, and a second drain electrode; and the second source electrode and the second drain electrode are both on a side of the second interlayer insulating layer away from the substrate, and are respectively connected to two ends of the second semiconductor layer through vias extending through the first gate insulating layer, the first interlayer insulating layer, the second gate insulating layer and the second interlayer insulating layer.

In some embodiments, the second gate electrode is in the same layer as the light shielding layer; and the second source electrode and the second drain electrode are in the same layer as the first source electrode.

In some embodiments, the array substrate further includes: a light shielding layer trace, a gate layer trace and a second adapter electrode electrically connected together, the light shielding layer trace is in the same layer as the light shielding layer, the gate layer trace is in the same layer as the first gate electrode, and the second adapter electrode is in the same layer as the first source electrode.

In some embodiments, at least one edge of an orthographic projection of the light shielding layer on the substrate is within an orthographic projection of the first gate electrode on the substrate.

In some embodiments, a distance between the at least one edge of the orthographic projection of the light shielding layer on the substrate and an edge of the orthographic projection of the first gate electrode on the substrate is in a range from 0 to 2.0 micrometers.

In some embodiments, the light shielding layers in any two adjacent first thin film transistors in the same row are disconnected from each other.

In some embodiments, an edge of an orthographic projection of the first semiconductor layer on the substrate close to a disconnecting position is within an orthographic projection of a corresponding light shielding layer on the substrate.

In some embodiments, a distance is in a range from 0.3 micrometers to 1.0 micrometers between an edge of an orthographic projection of the corresponding light shielding layer on the substrate close to the disconnecting position and the edge of the orthographic projection of the corresponding first semiconductor layer on the substrate close to the disconnecting position.

In some embodiments, an orthographic projection of the light shielding layer on the substrate covers an orthographic projection of the first via on the substrate.

In some embodiments, a distance between an edge of the orthographic projection of the light shielding layer on the substrate and an edge of the orthographic projection of the first via on the substrate is in a range from 0.5 micrometers to 1.5 micrometers.

In some embodiments, an orthographic projection of the light shielding layer on the substrate covers an orthographic projection of the second signal line on the substrate.

In some embodiments, a distance between an edge of the orthographic projection of the light shielding layer on the substrate and the orthographic projection of the second signal line on the substrate is in a range from 0.3 micrometers to 2.0 micrometers.

In a second aspect, embodiments of the present disclosure provide a display apparatus, wherein the display apparatus includes the array substrate.

### BRIEF DESCRIPTION OF DRAWINGS

FIG. 1 is a schematic diagram of a structure of an array substrate according to an embodiment of the present disclosure.

FIG. 2 is a schematic plan view of a structure of a portion of the array substrate shown in FIG. 1.

FIG. 2′ is another schematic plan view of a structure of a portion of the array substrate shown in FIG. 1.

FIG. 3a is a schematic top view of a structure of an array substrate according to an embodiment of the present disclosure.

FIG. 3b is a schematic cross-sectional view of a structure of the display substrate shown in FIG. 3a taken along a line A-A′.

FIG. 3c is a schematic cross-sectional view of a structure of the display substrate shown in FIG. 3a taken along a line B-B′.

FIG. 3d is a schematic cross-sectional view of a structure of the display substrate shown in FIG. 3a taken along a line C-C′.

FIG. 4 is a schematic diagram of a first modified structure of a portion of the array substrate shown in FIG. 2.

FIG. 4′ is a schematic cross-sectional view of the structure shown in FIG. 4 taken along a line D-D′.

FIG. 5 is a diagram illustrating an influence of a size of a light shielding layer on a light leakage current.

FIG. 6 is a schematic diagram of a second modified structure of a portion of the array substrate shown in FIG. 2.

FIG. 7 is a schematic diagram of a third modified structure of a portion of the array substrate shown in FIG. 2.

FIG. 8 is a schematic diagram of a fourth modified structure of a portion of the array substrate shown in FIG. 2.

FIGS. 9a to 9k are schematic diagrams of intermediate structures corresponding to steps in a method for manufacturing an array substrate according to an embodiment of the present disclosure.

### DETAIL DESCRIPTION OF EMBODIMENTS

In order to enable one of ordinary skill in the art to better understand the technical solutions of the present disclosure, the present disclosure will be described in further detail with reference to the accompanying drawings and the detailed description.

Unless defined otherwise, technical or scientific terms used herein shall have the ordinary meaning as understood by one of ordinary skill in the art to which the present disclosure belongs. The terms “first”, “second”, and the like used in the present disclosure are not intended to indicate any order, quantity, or importance, but rather are used for distinguishing one element from another. Further, the term “a”, “an”, “the”, or the like used herein does not denote a limitation of quantity, but rather denotes the presence of at least one element. The term “comprising”, “including”, or the like, means that the element or item preceding the term contains the element or item listed after the term and its equivalent, but does not exclude other elements or items. The term “connected”, “coupled”, or the like is not limited to physical or mechanical connections, but may include electrical connections, whether direct or indirect connections. The terms “upper”, “lower”, “left”, “right”, and the like are used only for indicating relative positional relationships, and when the absolute position of an object being described is changed, the relative positional relationships may also be changed accordingly.

The thin film transistor used in the embodiments of the present disclosure may be a field effect transistor or other device having the same characteristic. In addition, transistors may be divided into N-type transistors and P-type transistors according to the characteristics of the transistors. In the following embodiments, the N-type transistors are used for explanation. In the case of adopting the N-type transistor, when a high-level signal is input to a gate electrode of the N-type transistor, it turns conductive between a source electrode and a drain electrode of the N-type transistor. The contrary is the case for the P-type transistors. It is contemplated that the implementation adopting the P-type transistors will be readily apparent to one of ordinary skill in the art without any creative, and therefore is within the scope of the embodiment of the present disclosure.

It should be further noted that in an array substrate provided in the embodiment of the present disclosure, a thin film transistor in a display region is referred to as a first thin film transistor, and a thin film transistor in a peripheral region is referred to as a second thin film transistor, where the first thin film transistor may be an oxide thin film transistor, a first semiconductor layer is an oxide semiconductor layer, the second thin film transistor may be a low temperature poly-silicon thin film transistor, and a second semiconductor layer is a low temperature poly-silicon semiconductor layer. It is understood that the first thin film transistor and the second thin film transistor may be other types of thin film transistors, which are not enumerated here.

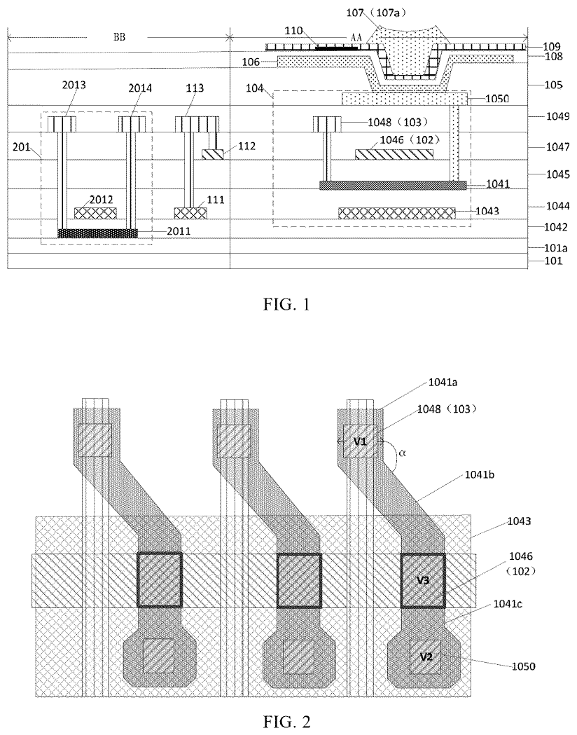

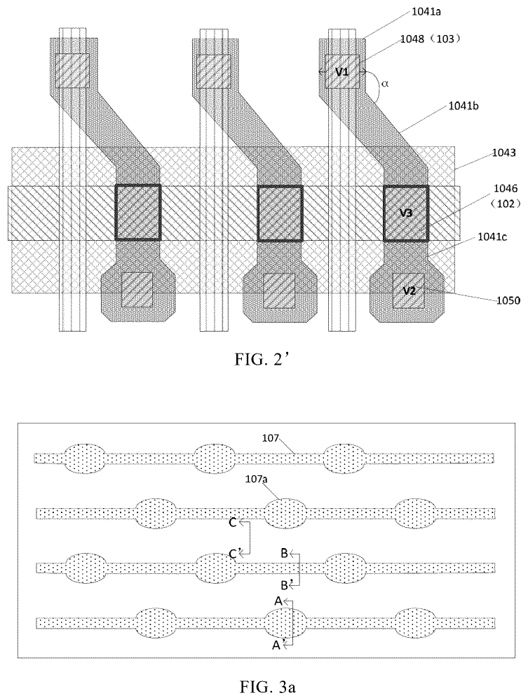

In a first aspect, an embodiment of the present disclosure provides an array substrate. FIG. 1 is a schematic diagram of a structure of an array substrate according to an embodiment of the present disclosure. FIG. 2 is a schematic plan view of a structure of a portion of the array substrate shown in FIG. 1. As shown in FIG. 1 and FIG. 2, the array substrate has a display region AA, and includes: a substrate 101, a first signal line and a second signal line above the substrate 101. The first signal line may be a trace extending along a first direction, and the second signal line may be a trace extending along a second direction. For example, the first signal line may be specifically a gate line 102, and the second signal line may be specifically a data line 103. In the following description, the gate line 102 and the data line 103 will be described in detail as an example. The gate line 102 and the data line 103 intersect with each other to define a pixel region. The array substrate further includes: an oxide thin film transistor 104 above the substrate 101 and in the pixel region, including: an oxide semiconductor layer 1041. The oxide semiconductor layer 1041 includes: a first connection portion 1041a, a second connection portion 1041b, and a third connection portion 1041c sequentially connected together, extending directions of the first connection portion 1041a and the third connection portion 1041c are the same as that of the data line 103, an orthographic projection of the first connection portion 1041a on the substrate 101 overlaps with an orthographic projection of the data line 103 on the substrate 101, an orthographic projection of the third connection portion 1041c on the substrate 101 falls between orthographic projections of two adjacent data lines 103 on the substrate 101, and overlaps with an orthographic projection of the gate line 102 on the substrate 101, a first angle α is formed between the extending directions of the second connection portion 1041b and the first connection portion 1041a, and the first angle α is in a range from 90 degrees to 180 degrees.

The substrate 101 may be made of a rigid material such as glass, which can improve the carrying capacity of the substrate 101 for other layers above the substrate 101. Alternatively, the substrate 101 may be made of a flexible material such as polyimide (PI), which can improve the bending resistance and stretching resistance of the overall metal oxide thin film transistor, and prevent the substrate 101 from being broken due to the stress generated when the substrate 101 is bent, stretched, or twisted, thereby avoiding the open circuit. In practical applications, the material of the substrate 101 may be selected reasonably according to actual requirements, so as to ensure that the metal oxide thin film transistor has good performances.

It can be understood that a buffer layer 101a may further be disposed on the substrate 101, and may be made of at least one of silicon nitride (SiN) and silicon oxide (SiO₂), and may be a single-layer structure made of a single material, or a multi-layer structure made of different materials, where a layer in contact with a low temperature poly-silicon semiconductor layer 2011 is a SiO₂ layer, so as to prevent gases such as water and oxygen from invading into other layers above the substrate 101 from one side of the substrate 101 to damage the array substrate. The buffer layer 101a may specifically be a laminating structure made of a silicon nitride (SiN) and silicon oxide (SiO₂), wherein the silicon nitride (SiN) has a thickness in a range from 300 Å to 2000 Å and the silicon oxide (SiO₂) has a thickness in a range from 1000 Å to 5000 Å.

The gate line 102 may be made of a metal material, such as one of molybdenum (Mo), aluminum (Al), and titanium (Ti), or an alloy of these materials, and may be a single-layer structure or a multi-layer structure. The data line 103 may also be made of the same material as the gate line 102. The gate line 102 may extend along the first direction above the substrate 101, and the data line 103 extends along the second direction above the substrate 101, wherein the first direction and the second direction intersect with each other and are parallel to the substrate 101. For example, the first direction may be a row direction, and the second direction may be a column direction. Specifically, the extending directions of the gate line 102 and the data line 103 are perpendicular to each other. The gate line 102 and the data line intersect with each other to define the pixel region in which a pixel driving circuit is disposed. Each gate line 102 may provide a gate signal to the pixel driving circuits in the same row, and each data line 103 may provide a data signal to the corresponding pixel driving circuits to drive liquid crystal molecules in the corresponding pixel regions to rotate, thereby implementing a display function.

Each oxide thin film transistor 104 is disposed in the corresponding pixel region, and includes: the oxide semiconductor layer 1041. The oxide semiconductor layer 1041 may be made of at least one of indium gallium zinc oxide (IGZO), indium gallium tin oxide (IGTO), and indium tin zinc oxide (ITZO), so that the oxide thin film transistor 104 has a small leakage current.

The oxide semiconductor layer 1041 includes: the first connection portion 1041a, the second connection portion 1041b, and the third connection portion 1041c sequentially connected together, the second connection portion 1041b is located between the first connection portion 1041a and the third connection portion 1041c, and two ends of the second connection portion 1041b may be connected to the first connection portion 1041a and the third connection portion 1041c, respectively. An orthographic projection of the first connection portion 1041a on the substrate 101 may overlap with an orthographic projection of the corresponding data line 103 on the substrate 101, and each of the first connection portion 1041a and the second connection portion 1041b may be processed to be transformed into a conductor portion, and serve as a source contact region. An orthographic projection of a portion of the third connection portion 1041c on the substrate 101 may overlap with an orthographic projection of the corresponding gate line 102 on the substrate 101, a region (the portion) of the third connection portion 1041c overlapping with the corresponding gate line 102 may serve as a channel, wherein a region (a portion) of the third connection portion 1041c not overlapping with the corresponding gate line 102 may be processed to be transformed into a conductor portion, a portion of the third connection portion 1041c close to the second connection portion 1041b is connected to the second connection portion 1041b, and a portion of the third connection portion 1041c away from the second connection portion 1041b serves as a drain contact region.

The first connection portion 1041a and the third connection portion 1041c may have the same extending direction. In particular, the extending directions of the first connection portion 1041a and the third connection portion 1041c may be the same as the data line 103. Each third connection portion 1041c is located between two data lines 103 adjacent to the third connection portions 1041c. The first angle α is formed between the extending directions of the second connection portion 1041b and the first connection portion 1041a, and the first angle α is in a range from 90 degrees to 180 degrees, for example, 120 degrees.

In the array substrate provided by the embodiment of the present disclosure, the oxide semiconductor layer 1041 of the oxide thin film transistor 104 is in a bent state, an orthographic projection of the first connection portion 1041a of the oxide semiconductor layer 1041 on the substrate 101 overlaps with an orthographic projection of the corresponding data line 103 on the substrate 101, so as to facilitate the connection of the first connection portion 1041a with the data line 103. The orthographic projection of the third connection portion 1041c on the substrate 101 overlaps with the orthographic projection of the corresponding gate line 102 on the substrate 101, and therefore it is not necessary to protrude a portion of the gate line 103 towards the pixel region and take the portion of the gate line 103 as a first gate electrode of the oxide thin film transistor 104 (which will be described in detail later), so that the shielding of the first gate electrode to the pixel region can be reduced, the aperture ratio of the pixel region can be increased, and the transmittance of light can be improved. Meanwhile, a position of the channel of the oxide thin film transistor 104 may be adjusted by controlling the bending angle (i.e., the first angle α) of the second connection portion 1041b, which is beneficial to improving the pixel density of the array substrate to meet the requirement of the user on the high PPI. Moreover, a leakage current of the oxide semiconductor layer 1041 of the oxide thin film transistor 104 can be reduced, and the oxide semiconductor layer 1041 is of a transparent structure, so that a display effect of the array substrate can be further improved.

In some embodiments, as shown in FIGS. 1 and 2, each oxide thin film transistor 104 further includes: a light shielding layer 1043, a second gate insulating layer 1045, a first gate electrode 1046, a second interlayer insulating layer 1047, and a first source electrode 1048, the light shielding layer 1043 is located above the substrate 101, the second gate insulating layer 1045 covers the oxide semiconductor layer 1041, the first gate electrode 1046 is a part of the gate line 102 and is located on a side of the second gate insulating layer 1045 away from the substrate 101, the second interlayer insulating layer 1047 covers the first gate electrode 1046, the first source electrode 1048 is a part of the data line 103 and located on a side of the second interlayer insulating layer 1047 away from the substrate 101, and the first source electrode 1048 is connected to the first connection portion 1041a through a first via V1 extending through the second gate insulating layer 1045 and the second interlayer insulating layer 1047.

The light shielding layer 1043 has a function of shielding light, which can prevent the light from being irradiated on the channel of the oxide semiconductor layer 1041 in the display region AA from one side of the substrate 101, so as to protect the oxide semiconductor layer 1041, prevent the light from affecting the performance of the oxide semiconductor layer 1041, and improve the stability of the oxide thin film transistor 104. The light shielding layer 1043 may be made of a metal material, such as one of copper, aluminum, and molybdenum, or an alloy of these materials, and may be a single-layer structure or a multi-layer structure.

The second gate insulating layer 1045 may be made of at least one of silicon nitride (SiN), and silicon oxide (SiO₂), which may be a single-layer structure made of a single material, or a multi-layer structure made of different materials, and may have a thickness in a range from 500 Å to 3000 Å. The second gate insulating layer 1045 can protect the oxide semiconductor layer 1041, to avoid the short circuit between the oxide semiconductor layer 1041 and other layers on the second gate insulating layer 1045.

The first gate electrode 1046 may be a part of the gate line 102, and may be formed while forming the gate line 102, and may be made of a metal material. For example, the first gate electrode 1046 may be made of one of molybdenum (Mo), aluminum (Al), and titanium (Ti), or an alloy of these materials, and may be a single-layer structure or a multi-layer structure, and may have a total thickness in a range from 2000 Å to 10000 Å.

The second interlayer insulating layer 1047 may be made of at least one of silicon nitride (SiN), and silicon oxide (SiO₂), may be a single-layer structure made of a single material or a multi-layer structure made of different materials, and may have a thickness in a range from 3000 Å to 10000 Å. The second interlayer insulating layer 1047 can avoid the short circuit between the first gate electrode 1046 and other layers on the second interlayer insulating layer 1047.

The first source electrode 1048 may be a part of the data line 103, may be formed while forming the data line 103, and may be made of a metal material. For example, the first source electrode 1048 may be made of one of molybdenum (Mo), aluminum (Al), titanium (Ti), or an alloy of these materials, may be a single-layer structure, or may be a multi-layer structure, and may have an overall thickness in a range from 2000 Å to 10000 Å. The first source electrode 1048 is connected to the first connection portion 1041a of the oxide semiconductor layer 1041 through the first via V1, and a data signal provided from the data line 103 may be input to the first connection portion 1041a of the oxide semiconductor layer 1041.

In some embodiments, as shown in FIG. 2, a width of the first connection portion 1041a is greater than a width of the corresponding first via V1 by 0 to 3 micrometers on at least one side along the extending direction of the gate line 102.

The first source electrode 1048 is connected to the first connection portion 1041a through the first via V1 extending through the second gate insulating layer 1045 and the second interlayer insulating layer 1047. The width of the first connection portion 1041a is compensated at a position corresponding to the first via V1, so that the width of the first connection portion 1041a is greater than the width of the corresponding first via V1 by 0 to 3 micrometers on the at least one side, which can avoid a short circuit caused by a fact that a depth of the first via V1 is excessively large due to an excessively large OL (Overlay) deviation and an excessively large etching deviation so that the first via V1 reaches the light shielding layer 1043 when forming the first via V1 by etching. For example, the width of the first connection portion 1041a is greater than the width of the corresponding first via V1 by 0 to 3 micrometers on each of both sides, as indicated by arrows on both sides of the first via V1 in FIG. 2. Specifically, a width of the first via V1 along the extending direction of the data line 103 may be in a range from 1.9 micrometers to 2.5 micrometers, for example, 1.9 micrometers. It is understood that the width of the first via V1 along the extending direction of the gate line 102 may also be in a range from 1.9 micrometers to 2.5 micrometers, for example, 1.9 micrometers. The first via V1 may be formed as a regular square via, or a circular via, or a via with other shape. For example, in practical applications, the first via V1 is a circular via.

In some embodiments, as shown in FIGS. 1 and 2, an orthographic projection of the first via V1 on the substrate 101 is outside an orthographic projection of the light shielding layer 1043 on the substrate 101.

The orthographic projection of the first via V1 on the substrate 101 and the orthographic projection of the light shielding layer 1043 on the substrate 101 may not overlap with each other. Even if the depth of the first via V1 is excessively large due to the excessively large OL deviation and the excessively large etching deviation, it can avoid the short circuit caused by a fact that the first via V1 reaches the light shielding layer 1043 when forming the first via V1 by etching. Specifically, a distance between an edge of the orthographic projection of the first via V1 on the substrate 101 close to the light shielding layer 1043 and an edge of the orthographic projection of the light shielding layer 1043 on the substrate close to the first via V1 is in a range from 0.5 micrometers to 10 micrometers, for example, 0.5 micrometers.

A width of the data line 103 is set so that it necessarily prevents the light transmittance from being affected by occupying a large area while ensuring the transmission of the data signals. Specifically, as shown in FIGS. 1 and 2, the width of the data line 103 along the extending direction of the gate line 102 may be set in a range from 1.3 to 1.5 micrometers, for example, to be 1.3 micrometers.

In some embodiments, as shown in FIGS. 1, 2 and 2′, an orthographic projection of a second via V2 on the substrate 101 at least partially overlaps with the orthographic projection of the light shielding layer 1043 on the substrate 101.

The orthographic projection of the second via V2 on the substrate 101 and the orthographic projection of the light shielding layer 1043 on the substrate 101 may overlap with each other. For example, in FIG. 2, the orthographic projection of the second via V2 on the substrate 101 is within the orthographic projection of the light shielding layer 1043 on the substrate 101. Alternatively, in FIG. 2′, the orthographic projection of the second via V2 on the substrate 101 only partially overlaps with the orthographic projection of the light shielding layer 1043 on the substrate 101. The light shielding layer 1043 may at least partially cover the position of the second via V2, so as to avoid the light leakage at the second via V2 and prevent the display effect from being affected.

In some embodiments, as shown in FIGS. 1 and 2, the oxide thin film transistor 104 further includes: a first passivation layer 1049 on a side of the first source electrode 1048 away from the substrate 101, and a first adapter electrode 1050 on a side of the first passivation layer 1049 away from the substrate 101, and the first adapter electrode 1050 is connected to the third connection portion 1041c through the second via V2 extending through the first passivation layer 1049, the second interlayer insulating layer 1047, and the second gate insulating layer 1045.

The first passivation layer 1049 may be made of at least one of silicon nitride (SiN) and silicon oxide (SiO₂), and may be a single-layer structure made of a single material, or a multi-layer structure made of different materials. The first passivation layer 1049 may avoid a short circuit between the first source electrode 1048 and other layers on the first passivation layer 1049.

The first adapter electrode 1050 and the first source electrode 1048 are disposed in different layers, so that a short circuit between the first adapter electrode 1050 and the first source electrode 1048 due to a large number of conductive layers disposed in the same layer can be avoided. Meanwhile, the first adapter electrode 1050 may be made of a transparent conductive material such as indium tin oxide (ITO), so as to prevent the first adapter electrode 1050 from shielding light and improve the overall light transmittance of the array substrate.

In some embodiments, as shown in FIGS. 1 and 2, at a position of the second via V2 along the extending direction of the gate line 102, a width of the third connection portion 1041c is greater than a width of the second via V2 by 0 to 3 micrometers.

The first adapter electrode 1050 is connected to the third connection portion 1041c through the second via V2 extending through the first passivation layer 1049, the second interlayer insulating layer 1047 and the second gate insulating layer 1045. The width of the third connection portion 1041c is compensated at a position corresponding to the second via V2, so that the width of the third connection portion 1041c is greater than the width of the corresponding second via V2 by 0 to 3 micrometers, which can avoid a short circuit caused by a fact that a depth of the second via V2 is excessively large due to an excessively large OL deviation and an excessively large etching deviation so that the second via V2 reaches the light shielding layer 1043 when forming the second via V2 by etching. Specifically, the width of the second via V2 along the extending direction of the data line 103 may be in a range from 1.9 micrometers to 2.5 micrometers, for example, 1.9 micrometers. It is understood that a width of the second via V2 along the extending direction of the gate line 102 may also be in a range from 1.9 micrometers to 2.5 micrometers, for example, 1.9 micrometers. The second via V2 may be formed as a regular square via to facilitate the connection between the first adapter electrode 1050 and the third connection portion 1041c.

In some embodiments, as shown in FIGS. 1 and 2, a distance between the second via V2 and the data line 103 adjacent to the second via V2 is in a range from 1.8 micrometers to 2.5 micrometers.

Each third connection portion 1041c is disposed between the data lines 103 adjacent to the third connection portion 1041c, each second via V2 corresponding to the third connection portion is also disposed between the adjacent data lines 103, and there is the distance between the second via V2 and each of the adjacent data lines 103, so that it is avoided that the data lines 103 are broken when forming the second vias V2 by etching, thereby avoiding the open circuit and preventing the transmission of the data signals from being affected. Specifically, the distance between the second via V2 and each of the adjacent data lines 103 is in a range from 1.8 micrometers to 2.5 micrometers, for example, 1.8 micrometers.

In some embodiments, as shown in FIGS. 1 and 2, the array substrate further includes: a planarization layer 105 on the first adapter electrode 1050, and a pixel electrode 106 on the planarization layer 105, and the pixel electrode 106 is connected to the first adapter electrode 1050 through a third via V3 extending through the planarization layer 105.

The planarization layer 105 may be disposed on the first adapter electrode 1050, and may be made of an organic material such as acryl, resin, polyimide, or benzocyclobutene, which may be specifically selected according to actual needs. The first adapter electrode 1050 may be planarized by forming the planarization layer 105, to form a relatively flat surface of the first adapter electrode 1050 for facilitating adhesion of other layers on the first adapter electrode 1050. In addition, due to the existence of the planarization layer 105, a distance between the first adapter electrode 1050 and other conductive layer in the oxide thin film transistor 104 can be increased, and a parasitic capacitance generated between the first adapter electrode 1050 and other conductive layer on the first adapter electrode 1050 can be avoided.

The pixel electrode 106 may be disposed on the planarization layer 105, and may be made of a transparent conductive material such as indium tin oxide (ITO), so as to prevent the pixel electrode 106 from shielding light and improve the overall light transmittance of the array substrate. The pixel electrode 106 may be electrically connected to the first adapter electrode 1050 through a third via V3 extending through the planarization layer 105, to input a data signal to the pixel electrode 106. Specifically, a width of the third via V3 along the extending direction of the gate line 103 is in a range from 2.5 micrometers to 3.0 micrometers, for example, 2.5 micrometers, to ensure stable connection between the pixel electrode 106 and the third connection portion 1041c.

In some embodiments, as shown in FIGS. 1 and 2, an orthographic projection of the third via V3 on the substrate 101 is within the orthographic projection of the light shielding layer 1043 on the substrate 101.

The light shielding layer 1043 may shield the third via V3, so as to avoid the light leakage at a position of the third via V3, and therefore, prevent the display effect from being affected. Specifically, along the extending direction of the gate line 102, a distance between an edge of the orthographic projection of the third via V3 on the substrate 101 and an edge of the orthographic projection of the light shielding layer 1043 on the substrate 101 is in a range from 1.0 micrometer to 1.5 micrometers, for example, 1.0 micrometer.

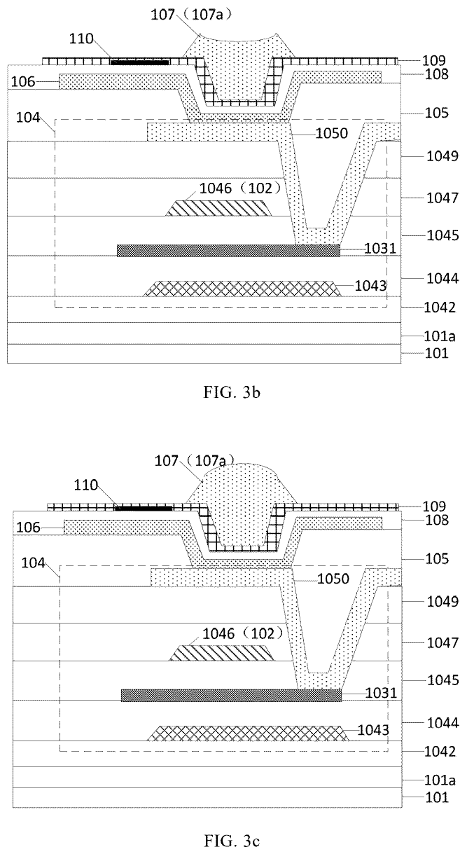

In some embodiments, as shown in FIGS. 1 and 2, the array substrate further includes: at least one support structure 107 located on the pixel electrode 106 and at a position of the third via V3. As shown in FIG. 3a, an extending direction of the support structure 107 is the same as that of the gate line 102.

Each support structure 107 may be embedded in the corresponding third via V3, and may be formed as a stripe structure along the extending direction of the gate line 102 and across the entire array substrate. When a display panel is formed, each support structure 107 may support a corresponding spacer in a color filter substrate, so as to prevent the spacer from sliding off, prevent a display device in the array substrate from being scratched, and therefore, prevent the display effect from being affected.

In some embodiments, as shown in FIGS. 1 and 2, an orthographic projection of each support structure 107 on the substrate 101 covers the orthographic projection of the corresponding third via V3 on the substrate 101.

Each support structure 107 extends across the entire array substrate. Each support structure 107 may be disposed at a position of the array substrate corresponding to the spacer in the color filter substrate where the support structure 107 has a large area, and the orthographic projection of each support structure 107 on the substrate 101 covers the orthographic projection of the corresponding third via V3 on the substrate 101, so as to provide a large standing platform for the corresponding spacer in the color filter substrate, to prevent the spacer from sliding off, prevent the display device in the array substrate from being scratched, and therefore, prevent the display effect from being affected. As shown in FIG. 3a, each support structure 107 has a large width at a position corresponding to the spacer in the color filter substrate, and has a small width at other positions.

In some embodiments, each support structure 107 is formed with a concave portion 107a at a portion of the support structure 107 corresponding to the spacer supported by the support structure 107, and an orthographic projection of the concave portion 107a on the substrate 101 overlaps with an orthographic projection of the corresponding third via V3 on the substrate 101.

As shown in FIG. 3b, in a cross section of the array substrate taken along a line A-A′, each support structure 107 is formed with the concave portion 107a at a portion of the support structure 107, and a bottom of the spacer may be clamped by the concave portion 107a, so that the spacer is prevented from falling off from the standing platform to scratch the display device in the array substrate, and therefore, the display effect is prevented from being affected. A top surface of the support structure 107 is not planar, and generally has a convex shape for process reasons, and an edge of the top surface of the support structure 107 may have a slope angle in a range from 30 degrees to 70 degrees. As shown in FIG. 3c, in a cross section of the array substrate taken along a line B-B′, the support structure 107 does not support the spacers at other positions of the support structure 107, and therefore is unnecessarily shaped to have the concave portion 107a, and the surface of the support structure 107 may naturally be shaped into the convex shape, so as to reduce the process difficulty. Meanwhile, as shown in FIGS. 3b and 3c, a slope angle of an edge of the light shielding layer 1043 may be in a range from 20 degrees to 45 degrees, and a slope angle of an edge of the first gate electrode 1046 may be in a range from 30 degrees to 60 degrees, so as to ensure that other layers may be smoothly disposed on the light shielding layer 1043 and the first gate electrode 1046, and to prevent the layers on the light shielding layer 1043 and the first gate electrode 1046 from being punctured due to excessive slope angles and therefore, prevent the performance of the layers from being affected. A slope angle of an edge of the via corresponding to the first adapter electrode 1050 may be in a range from 60 degrees to 80 degrees, so as to ensure that the first adapter electrode 1050 cannot be broken in the via, thereby ensuring the connection stability.

In some embodiments, as shown in FIG. 3d, in a cross-section of the array substrate taken along a line C-C′, no support structure 107 is disposed at a position where the first source electrode 1048 and the oxide semiconductor layer 1041 of the oxide thin film transistor 104 are connected to each other through the first via V1, and the planarization layer and the first passivation layer may be filled within the first via V1.

In some embodiments, as shown in FIG. 1, the array substrate further includes: a second passivation layer 108 and a common electrode 109 between the pixel electrode 106 and the support structure 107. The common electrode 109 is made of a transparent metal oxide.

The second passivation layer 108 may be made of at least one of silicon nitride (SiN), and silicon oxide (SiO₂), and may be a single-layer structure made of a single material, or a multi-layer structure made of different materials. The second passivation layer 108 may avoid a short circuit between the pixel electrode 106 and the common electrode 109.

The common electrode 109 may be disposed on the second passivation layer 108, and be made of transparent conductive materials such as indium tin oxide (ITO), to prevent the common electrode 109 from shielding light, and improve the overall light transmittance of the array substrate.

In some embodiments, as shown in FIG. 1, the array substrate further includes: a metal layer 110 on the second passivation layer 108, and an orthographic projection of the metal layer 110 on the substrate 101 is located between orthographic projections of adjacent pixel electrodes 106 on the substrate 101.

The metal layer 110 may be directly embedded into the common electrode 109, and therefore the metal layer 110 may be directly connected to the common electrode 109, so that it is avoided to connect the metal layer 110 and the common electrode 109 through vias and the like, a contact resistance between the metal layer 110 and the common electrode 109 is prevented from being increased, and the process steps can be simplified, the process cost is saved, and a thickness of the array substrate can be reduced.

The metal layer 110 may be made of the same metal material as the first gate electrode 1046 or the first source electrode 1048 and the first adapter electrode 1050, and can shield light, so that crosstalk of light in adjacent pixel regions in the array substrate may be avoided, and therefore, the display effect of the array substrate may be improved. The metal layer 110 is electrically connected to the common electrode 109, so that a load on the common electrode 109 can be reduced, and a recovery capability of a common signal can be improved. In addition, the common signal may be transmitted to the metal layer 110, so that static electricity is prevented from being accumulated due to suspension of the metal layer 110, and the influence of the static electricity on the stability of the array substrate is avoided.

In some embodiments, as shown in FIG. 1, the array substrate further includes a peripheral region BB disposed on at least one side of the display region AA, and further includes: a low temperature poly-silicon thin film transistor 201 located above the substrate 101 and in the peripheral region BB, including: a low temperature poly-silicon layer 2011, a first gate insulating layer 1042, a second gate electrode 2012, a first interlayer insulating layer 1044, a second source electrode 2013 and a second drain electrode 2014, which are sequentially stacked above the substrate 101. The second source electrode 2013 and the second drain electrode 2014 are both located on a side of the second interlayer insulating layer 1047 away from the substrate 101, and are respectively connected to two ends of the low temperature poly-silicon layer 2011 through vias extending through the first gate insulating layer 1042, the first interlayer insulating layer 1044, the second gate insulating layer 1045 and the second interlayer insulating layer 1047.

The first gate insulating layer 1042 may be made of at least one of silicon nitride (SiN) and silicon oxide (SiO₂), and may be a single-layer structure made of a single material or a multi-layer structure made of different materials. The first gate insulating layer 1042 may specifically be a laminating structure of silicon nitride (SiN) and silicon oxide (SiO₂), and may have a total thickness in a range from 600 Å to 2000 Å.

The first interlayer insulating layer 1044 may be made of at least one of silicon nitride (SiN), and silicon oxide (SiO₂), may be a single-layer structure made of a single material, or a multi-layer structure made of different materials, and may have a thickness in a range from 1000 Å to 8000 Å.

In order to avoid that the low temperature poly-silicon semiconductor layer 2011 of the low temperature poly-silicon thin film transistor 201 and the oxide semiconductor layer 1041 of the oxide thin film transistor 104 influence each other in the manufacturing process, the low temperature poly-silicon semiconductor layer 2011 and the oxide semiconductor layer 1041 are generally located in different layers, respectively, and the low temperature poly-silicon semiconductor layer 2011 is formed firstly, and then the oxide semiconductor layer 1041 is formed, that is, the oxide semiconductor layer 1041 may be located on a side of the low temperature poly-silicon semiconductor layer 2011 away from the substrate 101. The insulating layer, such as the first gate insulating layer 1042, the first interlayer insulating layer 1044, the second gate insulating layer 1045, or the like, are further disposed between every two adjacent conductive layers, to avoid a short circuit between the two adjacent conductive layers.

The low temperature poly-silicon semiconductor layer 2011 may be disposed on the buffer layer 101a in the peripheral region BB, and may be made of an amorphous silicon material having a thickness in a range from 300 Å to 800 Å. The amorphous silicon material is converted into a poly-silicon material by a process such as laser annealing, and the poly-silicon material layer is patterned to form the low temperature poly-silicon semiconductor layer 2011. The amorphous silicon material may be specifically made of at least one of silicon (Si), germanium (Ge) and carbon (C), and may be a single-layer structure made of a single material or a multi-layer structure made of different materials. The low temperature poly-silicon thin film transistor 201 may provide a driving voltage for the array substrate for displaying, and the low temperature poly-silicon semiconductor layer 2011 can improve the mobility and realize the narrow border.

The array substrate combines the technical effects of the high mobility and the narrow border realized by the low temperature poly-silicon thin film transistor 201 and the display effect of the high transmittance realized by the metal oxide thin film transistor 104, so that when the array substrate is used in the display panel, the display effect can be further improved.

In some embodiments, as shown in FIG. 1, the second gate electrode 2012 is disposed in the same layer as the light shielding layer 1043, and the second source electrode 2013 and the second drain electrode 2014 are both disposed in the same layer as the first source electrode 1048.

The second gate electrode 2012 is disposed in the same layer as the light shielding layer 1043, the second source electrode 2013 and the second drain electrode 2014 are both arranged in the same layer as the first source electrode 1048, and structures arranged in the same layer may be made of the same material by the same manufacturing process, so that the process steps are simplified, and the manufacturing cost is saved.

In some embodiments, as shown in FIG. 1, the array substrate further includes: a light shielding layer trace 111, a gate layer trace 112 and a second adapter electrode 113 electrically connected together, the light shielding layer trace 111 and the light shielding layer 1043 are arranged in the same layer, the gate layer trace 112 and the first gate electrode 1046 are disposed in the same layer, and the second adapter electrode 113 is disposed in the same layer as the first source electrode 1048.

In practical applications, a signal trace, such as a signal trace connected to a signal output end of a gate driving circuit, is generally disposed in the layer where the first source electrode 1048 is located. The light shielding layer trace 111, the gate layer trace 112 and the second adapter electrode 113 electrically connected together may transmit a signal (e.g., a scan signal) in the signal trace to the first gate electrode 1046, so as to control the oxide thin film transistor 104 to be turned on or off. The light shielding layer trace 111 and the light shielding layer 1043 are arranged in the same layer, and may be made of the same material through the same manufacturing process, so that the process steps are simplified, and the manufacturing cost is saved. Similarly, the gate layer trace 112 and the first gate electrode 1046 are disposed in the same layer, and the second adapter electrode 113 and the first source electrode 1048 are disposed in the same layer, so as to simplify the process steps and save the manufacturing cost. In addition, the light shielding layer trace 111 may be connected to the light shielding layer 1043, and may transmit a signal to the light shielding layer 1043, so as to prevent the static electricity from being accumulated due to the light shielding layer 1043 being suspended, thereby avoiding the influence of the static electricity on the stability of the array substrate.

Generally, the light shielding layer 1043 of the oxide thin film transistor 104 in the display region AA of the array substrate completely covers the first gate electrode 1046, so as to effectively shield a channel of the oxide semiconductor layer 1041 under the first gate electrode 1046, and eliminate the influence of light on the performance of the oxide thin film transistor 104. However, the current array substrate is prone to light leakage, which affects the display effect of the array substrate.

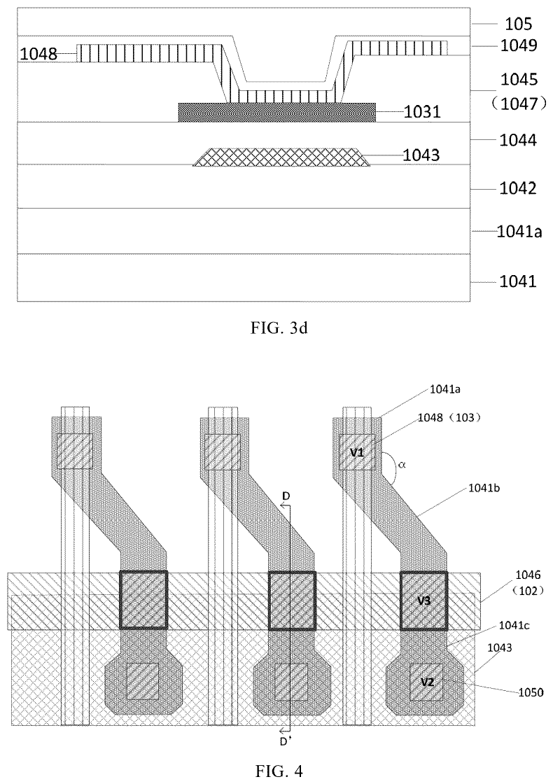

FIG. 4 is a schematic diagram of a first modified structure of a portion of the array substrate shown in FIG. 2. In the structure shown in FIG. 4, at least one edge of an orthographic projection of the light shielding layer 1043 on the substrate 101 is within an orthographic projection of the first gate electrode 1046 on the substrate 101.

In practical applications, the light shielding layer 1043 may be adjusted from an originally expanded structure to be a retracted structure, so that an edge of the light shielding layer 1043 may be located within the first gate electrode 1046. Specifically, a distance between the at least one edge of the orthographic projection of the light shielding layer 1043 on the substrate 101 and an edge of the orthographic projection of the first gate electrode 1046 on the substrate 101 is in a range from 0 to 2.0 micrometers. FIG. 4′ is a schematic cross-sectional view of the structure shown in FIG. 4 taken along a line D-D′. As shown in FIG. 4′, for the not retracted light shielding layer 1043, an overlapping distance between the light shielding layer 1043 and the first gate electrode 1046 is l1+l2, which can effectively shield the channel of the oxide semiconductor layer 1041. For the retracted light shielding layer 1043, a distance between the edges of the light shielding layer 1043 and the first gate electrode 1046 may be l1, so that the light transmittance is improved without affecting the performance of the channel of the oxide semiconductor layer 1041. For example, the distance l1 between the edges of the light shielding layer 1043 and the first gate electrode 1046 may be 0.6 micrometers or more.

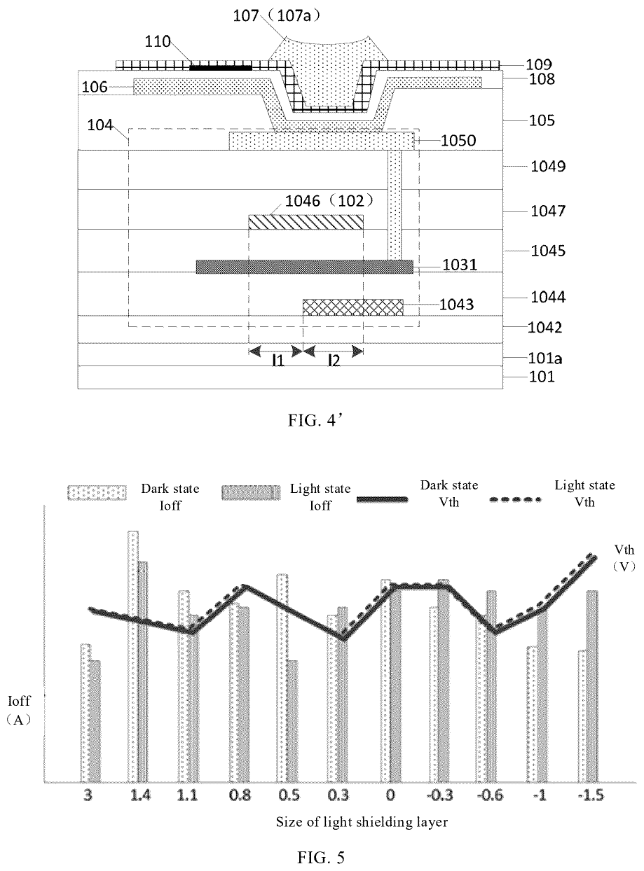

FIG. 5 is a diagram illustrating an influence of a size of a light shielding layer on a light leakage current. As shown in FIG. 5, for the light shielding layer 1043 which is retracted by 1.5 micrometers, the influence on the device is small, and the leakage current Ioff is in the order of 10E-12. Therefore, for the structure shown in FIG. 4, the light transmittance can be increased from the original 40% to 45% while ensuring that the influence on the light leakage current is small, thereby improving the display effect of the array substrate. Taking the structure shown in FIG. 4 as an example, the retracted edge of the light shielding layer 1043 may be an edge of the light shielding layer 1043 away from an opening region.

Generally, the light shielding layer 1043 of each oxide thin film transistor 104 in the display region AA of the array substrate is designed to extend across the entire array substrate in the lateral direction, and the light shielding layers 1043 of the oxide thin film transistors 104 in the same row have a one-piece structure, so that light shielding may be formed at a position where the light shielding is unnecessary, and therefore, the light transmittance is affected.

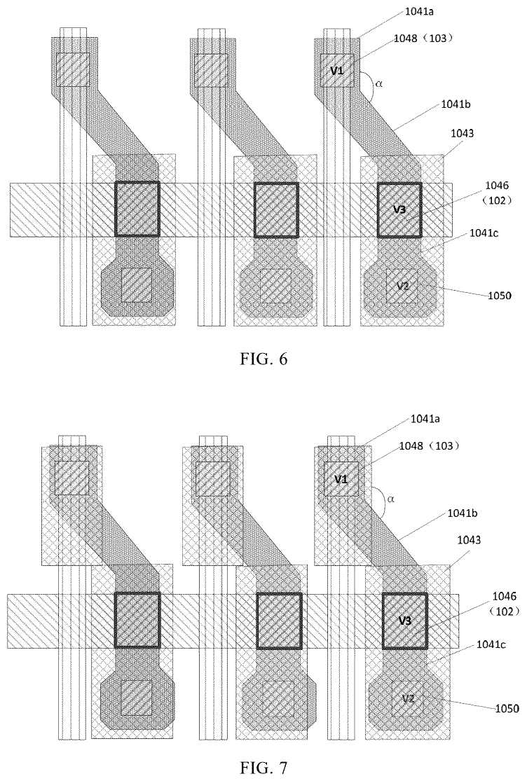

FIG. 6 is a schematic diagram of a second modified structure of a portion of the array substrate shown in FIG. 2. In the array substrate shown in FIG. 6, in the oxide thin film transistors 104 in the same row, the light shielding layers 1043 in any two adjacent oxide thin film transistors 104 are disconnected from each other. An edge of an orthographic projection of each oxide semiconductor layer 1041 on the substrate 101, close to a position where the light shielding layers 1043 are disconnected from each other (that is, a disconnecting position), is within an orthographic projection of a corresponding light shielding layer 1043 on the substrate 101.

The light shielding layers 1043 in any two adjacent oxide thin film transistors 104 are disconnected from each other, so that it can be avoided that the light shielding layers 1043 unnecessarily shield regions outside the channels of the oxide semiconductor layers 1041, and the light transmittance can be further improved while ensuring a good light shielding effect, thereby improving the display effect of the array substrate. Specifically, a distance is in a range from 0.3 micrometers to 1.0 micrometers between an edge of an orthographic projection of each light shielding layer 1043 on the substrate 101 close to the disconnecting position and the edge of the orthographic projection of the corresponding oxide semiconductor layer 1041 on the substrate 101 close to the disconnecting position.

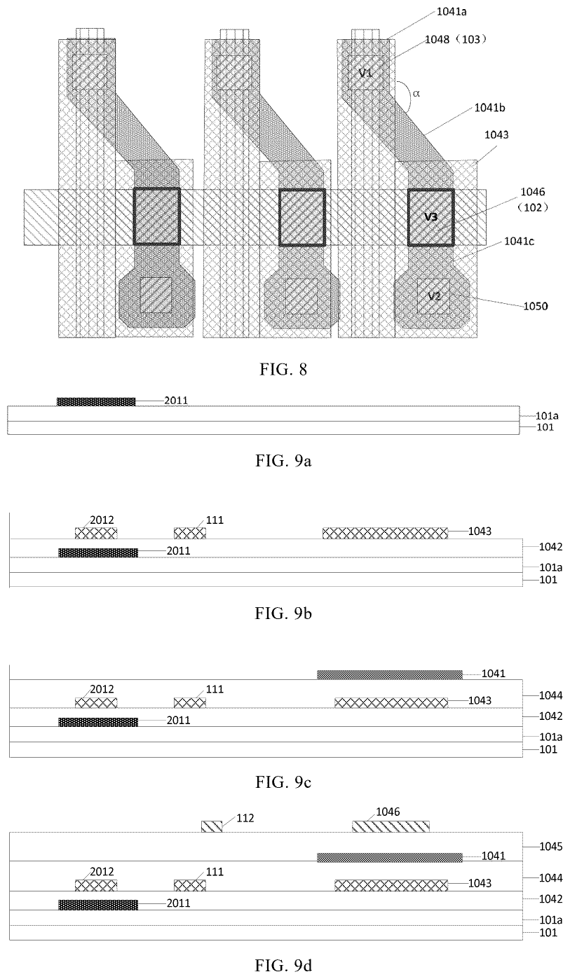

FIG. 7 is a schematic diagram of a third modified structure of a portion of the array substrate shown in FIG. 2. In the array substrate shown in FIG. 7, an orthographic projection of each light shielding layer 1043 on the substrate 101 covers an orthographic projection of the corresponding first via V1 on the substrate 101.

In practical applications, a depolarization phenomenon of light occurs at the position of the first via V1, which causes a light leakage at the position of the first via V1, and therefore, reduces a contrast of the array substrate. In the array substrate provided by the embodiment of the present disclosure, the light shielding layer 1043 may shield the first via V1, so that the light leakage at the position of the first via V1 is avoided, thereby preventing the light leakage from occurring, and improving the display effect of the array substrate. It is understood that vias at other positions in the array substrate may also be shielded in a similar manner, which is not described herein again.

Specifically, a distance between the edge of the orthographic projection of each light shielding layer 1043 on the substrate 101 and the edge of the orthographic projection of the corresponding first via V1 on the substrate 101 is in a range from 0.5 micrometers to 1.5 micrometers, so as to completely shield the first via V1 and avoid the light leakage.

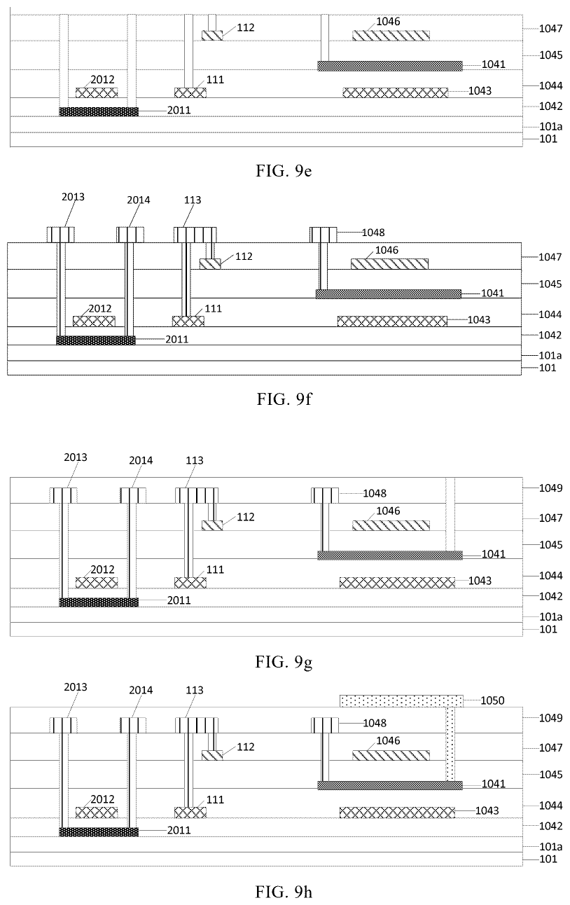

FIG. 8 is a schematic diagram of a fourth modified structure of a portion of the array substrate shown in FIG. 2. In the array substrate shown in FIG. 8, the orthographic projection of each light shielding layer 1043 on the substrate 101 covers an orthographic projection of the corresponding data line 103 on the substrate 101.

In an array substrate with an ultra high resolution, a line width of each data line 103 is often smaller than a width of the corresponding via, so it is necessary to compensate a width of a portion of the data line 103 at a position of the via. However, a vertical compensation design cannot be affected due to a diffraction problem of an exposure machine after the width of the data line 103 is compensated, and the actually compensated position of the data line 103 in the array substrate has a circular arc shape, which aggravates the depolarization phenomenon of light, so that the light leakage occurs more easily, thereby reducing the contrast of the array substrate.

In the array substrate provided by the embodiment of the present disclosure, each light shielding layer 1043 may shield the corresponding data line 103, so that the light leakage from the data line 103 is avoided, thereby preventing the light leakage from occurring, and improving the display effect of the array substrate. Specifically, the distance between the edge of the orthographic projection of the light shielding layer 1043 on the substrate 101 and the orthographic projection of the corresponding data line 103 on the substrate 101 is in a range from 0.3 micrometers to 2.0 micrometers.

It is understood that the array substrate may be modified by combining the structures shown in FIGS. 4, 6, 7 and 8, and the implementation principle is similar to that described above, and therefore, the detailed description is omitted here.

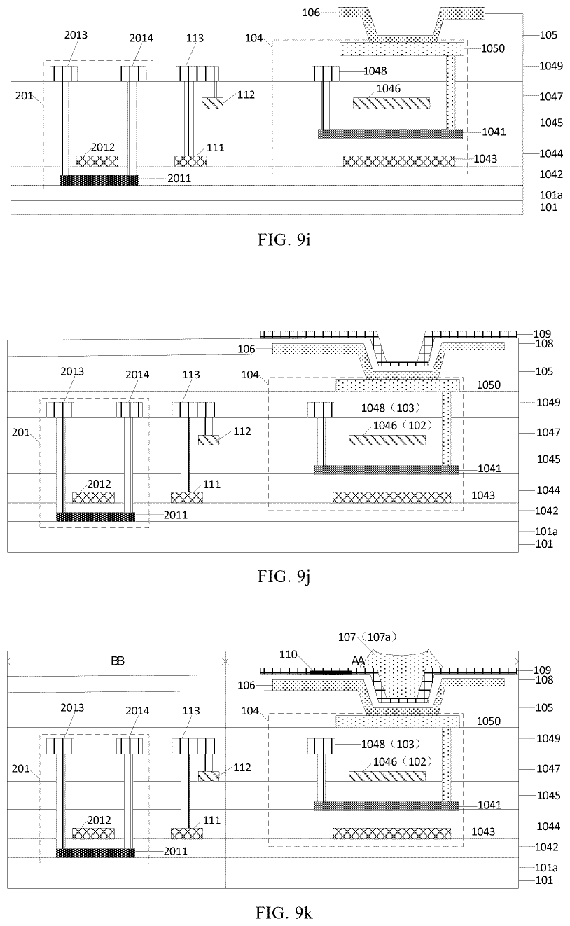

FIGS. 9a to 9k are schematic diagrams of intermediate structures corresponding to steps in a method for manufacturing an array substrate according to an embodiment of the present disclosure. A process flow for manufacturing an array substrate provided by the embodiment of the present disclosure will be described in further detail below with reference to the schematic diagrams of intermediate structures corresponding to the steps.

As shown in FIG. 9a, a buffer layer 101a is formed on a substrate 101 together with a layer of an amorphous silicon (a-Si) material, and then the amorphous silicon (a-Si) material is converted into a poly-silicon (P-Si) material by crystallization processes including laser irradiation and annealing processes and the like, and then a mask process and a dry etching process are performed on the poly-silicon (P-Si) material to form a pattern of a channel of a low temperature poly-silicon semiconductor layer 2011 of a low temperature poly-silicon thin film transistor 201 in the peripheral region BB. The buffer layer 101a may specifically be a laminating structure made of silicon nitride (SiN), and silicon oxide (SiO₂), wherein the silicon nitride (SiN) has a thickness in a range from 300 Å to 2000 Å, the silicon oxide (SiO₂) has a thickness in a range from 1000 Å to 5000 Å, and the low temperature poly-silicon semiconductor layer 2011 has a thickness in a range from 300 Å to 800 Å.

As shown in FIG. 9b, after the channel of the low temperature poly-silicon semiconductor layer 2011 is formed, a first gate insulating layer 1042 is formed without a mask. Then, a first conductive layer is formed, and a second gate electrode 2012 is formed by wet etching after a mask process. At the same time, the light shielding layer trace 111 and the light shielding layer 1043 may further be formed. The first gate insulating layer 1042 may specifically be a laminating structure made of silicon nitride (SiN) and silicon oxide (SiO₂), and may have a total thickness in a range from 600 Å to 2000 Å. A total thickness of the second gate electrode 2012 may be in a range from 1000 Å to 6000 Å. The light shielding layer 1043 and the second gate electrode 2012 may be distributed in a stripe shape, and may have a width in a range from 2 micrometers to 10 micrometers.

As shown in FIG. 9c, after the first conductive layer is formed, a first interlayer insulating layer 1044 is formed without a mask. Then, an oxide semiconductor layer 1041 is formed, and a pattern of a channel of the oxide semiconductor layer 1041 is formed by a mask process and a dry etching process. The first interlayer insulating layer 1044 may be made of at least one of silicon nitride (SiN) and silicon oxide (SiO₂), may be a single-layer structure made of a single material, or a multi-layer structure made of different materials. The first interlayer insulating layer 1044 may have a thickness in a range from 1000 Å to 8000 Å.

As shown in FIG. 9d, after the channel of the oxide semiconductor layer 1041 is formed, a second gate insulating layer 1045 is formed without a mask. Then, a second conductive layer is formed, and a first gate electrode 1046 is formed by a mask process and a wet etching process. The wet etching process is adopted for obtaining a smaller slope angle, thereby ensuring the good coverage of the upper insulating layer. At the same time, a gate layer trace 112 may further be formed. The second gate insulating layer 1045 may be made of at least one of silicon nitride (SiN), and silicon oxide (SiO₂), may be a single-layer structure made of a single material, or a multi-layer structure made of different materials, and may have a thickness in a range from 500 Å to 3000 Å. A total thickness of the first gate electrode 1046 may be in a range from 2000 Å to 10000 Å. A total thickness of the gate layer trace 112 may be in a range from 2000 Å to 10000 Å.

As shown in FIG. 9e, after the second conductive layer is formed, a second interlayer insulating layer 1047 is formed, and a photoresist is coated, and then, a mask process is performed to form a pattern of the openings in the layers in the peripheral region BB, and then an etching process is performed to form vias extending through the layers. The second interlayer insulating layer 1047 may be made of at least one of silicon nitride (SiN), and silicon oxide (SiO₂), may be a single-layer structure made of a single material or a multi-layer structure made of different materials, and may have a thickness in a range from 3000 Å to 10000 Å.

As shown in FIG. 9f, after the vias are formed, a third conductive layer is then formed. Specifically, a second source electrode 2013, a second drain electrode 2014, a first source electrode 1048 and a second adapter electrode 113 are formed through a mask process and a dry etching process, and the electrodes are electrically connected to other conductive layers through the corresponding vias. The second source electrode 2013, the second drain electrode 2014, and the first source electrode 1048 may be disposed in the same layer on the second interlayer insulating layer 1047, may be a single-layer structure made of a single material, or a multi-layer structure made of different materials, and may have a thickness in a range from 2000 Å to 10000 Å.

As shown in FIG. 9g, after the third conductive layer is formed, a first passivation layer 1049 is formed, and a via corresponding to the first adapter electrode 1050 is formed through a mask process and a dry etching process.

As shown in FIG. 9h, after the via corresponding to the first adapter electrode 1050 is formed, a fourth conductive layer is formed. Specifically, the first adapter electrode 1050 is formed through a mask process and a wet etching process, and the first adapter electrode 1050 is electrically connected to the oxide semiconductor layer 1041 through the via. The first adapter electrode 1050 may be made of a transparent conductive material such as indium tin oxide (ITO), to prevent the first adapter electrode 1050 from shielding light, thereby improving the overall light transmittance of the array substrate.

As shown in FIG. 9i, after the fourth conductive layer is formed, a planarization layer 105 is formed, and a via is formed through a mask process. Then, a pixel electrode 106 is formed. Specifically, the pixel electrode 106 is formed by a mask process and a wet etching process.

As shown in FIG. 9j, after the pixel electrode 106 is formed, a second passivation layer 108 is formed, and then a via is formed in the peripheral region BB through a mask process and a dry etching process. The display region AA has a PCI (Pixel layer and Common layer Inversion, i.e., the pixel electrode 106 being under a common electrode 109) structure, so that it is unnecessary to form a via in the display region AA. Then, the common electrode 109 is formed. Specifically, the common electrode 109 is formed through a mask process and a wet etching process.

As shown in FIG. 9k, taking into account the color crosstalk and the light leakage, a metal layer 110 may be formed under the common electrode 109, so as to eliminate the color crosstalk, reduce the load on the common electrode 109, and improve the recovery capability of the common signal. A support structure 107 is formed on the common electrode 109, to fill the formed concave portion, so that the position of the concave portion does not need to be planarized by using a filling material, and a standing space may be provided for the spacer, thereby preventing the spacer from sliding off to damage other display devices.

In a second aspect, embodiments of the present disclosure provide a display apparatus, including the array substrate as provided in any one of the above embodiments. Specifically, the display apparatus may be a virtual reality display apparatus or an augmented reality display apparatus, and has a resolution greater than or equal to 2000 PPI, so as to implement high-resolution display and meet the user's requirement for a high-resolution display picture. It should be noted that the implementation principle and the beneficial effects of the display apparatus provided in the embodiments of the present disclosure are the same as those of the array substrate provided in any one of the above embodiments, and are not described herein again.

It should be understood that the above embodiments are merely exemplary embodiments adopted to explain the principles of the present disclosure, and the present disclosure is not limited thereto. It will be apparent to one of ordinary skill in the art that various changes and modifications may be made therein without departing from the spirit and scope of the present disclosure, and such changes and modifications also fall within the scope of the present disclosure.

1. An array substrate comprising a display region, wherein the array substrate comprises: a substrate, a first signal line and a second signal line on one side of the substrate, the first signal line and the second signal line intersect with each other to define a pixel region, and the array substrate further comprises: a first thin film transistor above the substrate and in the pixel region;
the first thin film transistor comprises: a first semiconductor layer, and the first semiconductor layer comprises: a first connection portion, a second connection portion and a third connection portion sequentially connected together;
extending directions of the first connection portion and the third connection portion are the same as that of the second signal line, an orthographic projection of the first connection portion on the substrate overlaps with an orthographic projection of the second signal line on the substrate, an orthographic projection of the third connection portion on the substrate falls between orthographic projections of two adjacent second signal lines on the substrate, and overlaps with an orthographic projection of the first signal line on the substrate; and
a first angle is between extending directions of the second connection portion and the first connection portion, and the first angle is in a range from 90 degrees to 180 degrees.

2. The array substrate of claim 1, wherein the first thin film transistor further comprises: a light shielding layer, a second gate insulating layer, a first gate electrode, a second interlayer insulating layer and a first source electrode; and
the light shielding layer is above the substrate, the second gate insulating layer covers the first semiconductor layer, the first gate electrode is a part of the first signal line and is on a side of the second gate insulating layer away from the substrate, the second interlayer insulating layer covers the first gate electrode, the first source electrode is a part of the second signal line and is on a side of the second interlayer insulating layer away from the substrate, and the first source electrode is connected to the first connection portion through a corresponding first via extending through the second gate insulating layer and the second interlayer insulating layer.

3. The array substrate of claim 2, wherein a width of the first connection portion is greater than a width of the corresponding first via by 0 to 3 micrometers on at least one side along an extending direction of the first signal line.

4. The array substrate of claim 2, wherein an orthographic projection of the first via on the substrate is outside an orthographic projection of the light shielding layer on the substrate; and
a distance between an edge of the orthographic projection of the first via on the substrate close to the light shielding layer and an edge of the orthographic projection of the light shielding layer on the substrate close to the first via is in a range from 0.5 micrometers to 10 micrometers.

5. (canceled)

6. The array substrate of claim 2, wherein the array substrate further comprises: a first passivation layer on a side of the first source electrode away from the substrate, and a first adapter electrode on a side of the first passivation layer away from the substrate; and
the first adapter electrode is connected to the third connection portion through a second via extending through the first passivation layer, the second interlayer insulating layer, and the second gate insulating layer.

7. The array substrate of claim 6, wherein the array substrate further comprises: a planarization layer on the first adapter electrode, and a pixel electrode on the planarization layer; and
the pixel electrode is connected to the first adapter electrode through a third via extending through the planarization layer.

8. The array substrate of claim 7, wherein the first via has a width in a range from 1.9 micrometers to 2.5 micrometers along an extending direction of the second signal line, the second via has a width in a range from 1.9 micrometers to 2.5 micrometers along an extending direction of the first signal line, and the third via has a width in a range from 2.5 micrometers to 3.0 micrometers along the extending direction of the first signal line.

9. The array substrate of claim 7, wherein an orthographic projection of the third via on the substrate is within an orthographic projection of the light shielding layer on the substrate; and
along an extending direction of the first signal line, a distance between an edge of the orthographic projection of the third via on the substrate and an edge of the orthographic projection of the light shielding layer on the substrate is in a range from 1.0 micrometer to 1.5 micrometers.

10. (canceled)

11. The array substrate of claim 7, wherein the array substrate further comprises: a support structure on the pixel electrode and at a position of the third via; and
an extending direction of the support structure is the same as that of the first signal line.

12. The array substrate of claim 11, wherein an orthographic projection of the support structure on the substrate covers an orthographic projection of the third via on the substrate.

13. The array substrate of claim 11, wherein the support structure comprises a concave portion at a portion of the support structure corresponding to a spacer supported by the support structure, and an orthographic projection of the concave portion on the substrate overlaps with an orthographic projection of the corresponding third via on the substrate.

14. The array substrate of claim 11, wherein the support structure has a slope angle in a range from 30 degrees to 70 degrees.

15. The array substrate of claim 11, wherein the array substrate further comprises: a second passivation layer and a common electrode between the pixel electrode and the support structure; and
the common electrode is made of a transparent metal; and
wherein the array substrate further comprises: a metal layer on the second passivation layer; and
an orthographic projection of the metal layer on the substrate is between orthographic projections of adjacent pixel electrodes on the substrate.

16. (canceled)

17. The array substrate of claim 2, wherein the array substrate further comprises a peripheral region on at least one side of the display region, and further comprises: a second thin film transistor above the substrate and in the peripheral region;
the second thin film transistor comprises: a second semiconductor layer, a first gate insulating layer, a second gate electrode, a first interlayer insulating layer, a second source electrode, and a second drain electrode; and
the second source electrode and the second drain electrode are both on a side of the second interlayer insulating layer away from the substrate, and are respectively connected to two ends of the second semiconductor layer through vias extending through the first gate insulating layer, the first interlayer insulating layer, the second gate insulating layer and the second interlayer insulating layer.

18. The array substrate of claim 17, wherein the second gate electrode is in the same layer as the light shielding layer; and
the second source electrode and the second drain electrode are in the same layer as the first source electrode; and
the array substrate further comprises: a light shielding layer trace, a gate layer trace and a second adapter electrode electrically connected together, the light shielding layer trace is in the same layer as the light shielding layer, the gate layer trace is in the same layer as the first gate electrode, and the second adapter electrode is in the same layer as the first source electrode.

19. (canceled)

20. The array substrate of claim 2, wherein at least one edge of an orthographic projection of the light shielding layer on the substrate is within an orthographic projection of the first gate electrode on the substrate; and
a distance between the at least one edge of the orthographic projection of the light shielding layer on the substrate and an edge of the orthographic projection of the first gate electrode on the substrate is in a range from 0 to 2.0 micrometers.

21. (canceled)

22. The array substrate of claim 2, wherein the light shielding layers in any two adjacent first thin film transistors in the same row are disconnected from each other;
an edge of an orthographic projection of the first semiconductor layer on the substrate close to a disconnecting position is within an orthographic projection of a corresponding light shielding layer on the substrate; and
a distance is in a range from 0.3 micrometers to 1.0 micrometers between an edge of an orthographic projection of the corresponding light shielding layer on the substrate close to the disconnecting position and the edge of the orthographic projection of the corresponding first semiconductor layer on the substrate close to the disconnecting position.

23-24. (canceled)

25. The array substrate of claim 2, wherein an orthographic projection of the light shielding layer on the substrate covers an orthographic projection of the first via on the substrate; and
a distance between an edge of the orthographic projection of the light shielding layer on the substrate and an edge of the orthographic projection of the first via on the substrate is in a range from 0.5 micrometers to 1.5 micrometers.

26. (canceled)

27. The array substrate of claim 2, wherein an orthographic projection of the light shielding layer on the substrate covers an orthographic projection of the second signal line on the substrate; and
a distance between an edge of the orthographic projection of the light shielding layer on the substrate and the orthographic projection of the second signal line on the substrate is in a range from 0.3 micrometers to 2.0 micrometers.

28. (canceled)

29. A display apparatus, wherein the display apparatus comprises the array substrate of claim 1.
